(19) United States
(12) Patent Application Publication
(10) Pub. No.: US 2025/0081649 A1
(43) Pub. Date: Mar. 6, 2025

(54) SOLID IMAGING DEVICE AND ELECTRONIC DEVICE

(71) Applicant: SONY SEMICONDUCTOR SOLUTIONS CORPORATION, KANAGAWA (JP)

(72) Inventors: TATSUYA NAKATA, KANAGAWA (JP); FUMIAKI SANO, KANAGAWA (JP)

(21) Appl. No.: 18/043,486

(22) PCT Filed: Aug. 30, 2021
(86) PCT No.: PCT/JP2021/031653

§ 371 Date: Feb. 28, 2023

(30) Foreign Application Priority Data
Sep. 11, 2020 (JP) 2020-153364

(51) Int. Cl. H01L 27/146; G01S 17/931; H04N 25/62; H04N 25/773

(52) U.S. Cl. CPC H10F 39/807; G01S 17/931; H04N 25/62; H04N 25/773; H10F 39/18; H10F 39/811

(57) ABSTRACT

A solid imaging device according to an aspect of the present disclosure includes: a photoelectric conversion region (102) that photoelectrically converts light, which is incident from a light incident surface, in an element region partitioned by an element isolation section (110); a first semiconductor region surrounding the photoelectric conversion region (102); a first contact that is in contact with the first semiconductor region; a first electrode that is provided in the element isolation section (110), extends from a side of the light incident surface along the element isolation section (110), and is in contact with the first contact; a second semiconductor region that is in contact with the first semiconductor region and has a first conductivity type same as that of the first semiconductor region; a third semiconductor region that is in contact with an opposite side of the side of the light incident surface in the second semiconductor region and has a second conductivity type opposite to the first conductivity type; a second contact that is in contact with the third semiconductor region; and a second electrode that is in contact with the second contact, in which one end of the first electrode which end is on the opposite side of the side of the light incident surface is placed on the side of the light incident surface compared to a contact surface between the second semiconductor region and the third semiconductor region in a height direction.

### FIELD

The present disclosure relates to a solid imaging device and an electronic device.

### BACKGROUND

In recent years, a single photon avalanche diode (SPAD) has been developed. The SPAD is an element that amplifies a charge generated by photoelectric conversion by avalanche amplification (also referred to as avalanche multiplication) and performs an output thereof as an electric signal. The avalanche amplification is a phenomenon in which current is multiplied by repetition of the following. That is, in an impurity diffusion region of PN junction, an electron accelerated by an electric field collides with lattice atoms and cut a bond thereof, and newly generated electrons collide with other lattice atoms and cut a bond thereof.

Such an SPAD is used in a solid imaging device that converts an amount of incident light into an electric signal. This solid imaging device is used, for example, in an electronic device such as a ranging device that measures a distance to an object from a time until light emitted from a light emitting section is reflected by the object and returns, or an imaging device that images the object. For example, SPADs are arrayed as pixels in a matrix, and the SPADs (SPAD pixels) are partitioned by an element isolation section (pixel isolation section).

In order to discharge a large current generated by the avalanche amplification from the SPADs, it is desirable to form a contact of a low-resistance ohmic contact. As a method of forming the contact of the low-resistance ohmic contact with respect to an impurity diffusion region formed in a semiconductor substrate, it is generally known to form a high-concentration impurity region in a contact section.

### CITATION LIST

### Patent Literature

Patent Literature 1: WO 2018/174090 A

### SUMMARY

### Technical Problem

Here, it is necessary to apply a high voltage in a reverse bias direction to a PN junction in order to acquire electric field intensity enough to generate avalanche amplification. However, when a distance from a PN junction region to the contact is short, a strong electric field is formed therebetween and a leakage current and a tunnel current are generated. For example, current may flow between an anode and a cathode even in the dark without light. Specifically, electrons and holes are emitted from a structure interface between the anode and the cathode or a defect level of a depletion layer, and that kind of charges pass through a high electric field region and is multiplied, whereby the leakage current flows. Furthermore, when a high electric field is generated between the anode and the cathode, current constantly flows as the tunnel current and a sufficient voltage is not applied at a pixel center through which signal charges pass, whereby the avalanche amplification (multiplication phenomenon) is not generated.

In order to avoid the generation of the leakage current and the tunnel current, for example, there is a method of increasing a distance from a PN junction region to the contact. However, it is difficult to increase the distance from the PN junction region to the contact while achieving miniaturization. In addition, it is difficult to achieve both miniaturization and securing of a withstand voltage. When voltage is applied to an electrode that is metal in the element isolation section, the voltage may deform a multiplication section (multiplication region) in the SPADs. When the multiplication section is deformed, deterioration in a multiplication characteristic and deterioration in a noise characteristic (such as dark current noise that causes an increase in a false count rate) are caused.

Thus, the present disclosure proposes a solid imaging device and electronic device capable of controlling deterioration in a multiplication characteristic and a noise characteristic.

### Solution to Problem

A solid imaging device according to an aspect of the present disclosure includes: a semiconductor substrate including a plurality of photoelectric conversion elements that photoelectrically converts light incident from a light incident surface; and an element isolation section that is provided in a lattice shape on the semiconductor substrate and partitions the plurality of photoelectric conversion elements, wherein the photoelectric conversion element includes a photoelectric conversion region that is provided in an element region partitioned by the element isolation section and that photoelectrically converts the light incident from the light incident surface and generates a charge, a first semiconductor region that is provided in the element region and that surrounds the photoelectric conversion region, a first contact that is provided in the element region and that is in contact with the first semiconductor region, a first electrode that is provided in the element isolation section, extends from a side of the light incident surface along the element isolation section, and is in contact with the first contact, a second semiconductor region that is provided in the element region, is in contact with the first semiconductor region, and has a first conductivity type same as that of the first semiconductor region, a third semiconductor region that is provided in the element region, is in contact with an opposite side of the side of the light incident surface in the second semiconductor region, and has a second conductivity type opposite to the first conductivity type, a second contact that is provided in the element region and in contact with the third semiconductor region, and a second electrode that is in contact with the second contact, and one end of the first electrode which end is on the opposite side of the side of the light incident surface is placed on the side of the light incident surface compared to a contact surface between the second semiconductor region and the third semiconductor region in a height direction.

### BRIEF DESCRIPTION OF DRAWINGS

FIG. 1 is a block diagram depicting a schematic configuration example of an electronic device according to a first embodiment.

FIG. 2 is a block diagram depicting a schematic configuration example of an image sensor according to the first embodiment.

FIG. 3 is a circuit diagram depicting a schematic configuration example of an SPAD pixel according to the first embodiment.

FIG. 4 is a diagram depicting a layout example of a color filter according to the first embodiment.

FIG. 5 is a diagram depicting a stacked structure example of the image sensor according to the first embodiment.

FIG. 6 is a vertical cross-sectional diagram depicting a cross-sectional structure example of a plane vertical to a light incident surface of the SPAD pixel according to the first embodiment.

FIG. 7 is a horizontal cross-sectional diagram depicting a cross-sectional structure example of an A-A plane in FIG. 6.

FIG. 8 is a first diagram of assistance in explaining voltage supply from the light incident surface of the SPAD pixel to an anode electrode according to the first embodiment.

FIG. 9 is a second diagram of assistance in explaining voltage supply from the light incident surface of the SPAD pixel to an anode electrode according to the first embodiment.

FIG. 10 is a circuit diagram depicting another schematic configuration example of an SPAD pixel according to the first embodiment.

FIG. 11 is a vertical cross-sectional diagram depicting a cross-sectional structure example of a plane vertical to a light incident surface of an SPAD pixel according to a second embodiment.

FIG. 12 is a vertical cross-sectional diagram depicting a cross-sectional structure example of a plane vertical to a light incident surface of an SPAD pixel according to a third embodiment.

FIG. 13 is a vertical cross-sectional diagram depicting a cross-sectional structure example of a plane vertical to a light incident surface of an SPAD pixel according to a fourth embodiment.

FIG. 14 is a vertical cross-sectional diagram depicting a cross-sectional structure example of a plane vertical to a light incident surface of an SPAD pixel according to a fifth embodiment.

FIG. 15 is a vertical cross-sectional diagram depicting a cross-sectional structure example of a plane vertical to a light incident surface of an SPAD pixel according to a sixth embodiment.

FIG. 16 is a vertical cross-sectional diagram depicting a cross-sectional structure example of a plane vertical to a light incident surface of an SPAD pixel according to a seventh embodiment.

FIG. 17 is a vertical cross-sectional diagram depicting a cross-sectional structure example of a plane vertical to a light incident surface of an SPAD pixel according to an eighth embodiment.

FIG. 18 is a vertical cross-sectional diagram depicting a cross-sectional structure example of a plane vertical to a light incident surface of an SPAD pixel according to a ninth embodiment.

FIG. 19 is a diagram depicting a schematic configuration example of an imaging device.

FIG. 20 is a diagram depicting a schematic configuration example of a ranging device.

FIG. 21 is a block diagram depicting an example of schematic configuration of a vehicle control system.

FIG. 22 is a diagram of assistance in explaining an example of installation positions of an outside-vehicle information detecting section and an imaging section.

### DESCRIPTION OF EMBODIMENTS

In the following, embodiments of the present disclosure will be described in detail on the basis of the drawings. Note that in the following embodiment, overlapped description is omitted by assignment of the same reference sign to the same parts.

Also, the present disclosure will be described in the following order of items.
1. First Embodiment
1-1. Electronic device
1-2. Solid imaging device
1-3. SPAD pixel
1-4. Schematic operation example of the SPAD pixel
1-5. Layout example of a color filter
1-6. Stacked structure example of the solid imaging device
1-7. Example of a cross-sectional structure of the SPAD Pixel
1-8. Positional relationship between an N+ type semiconductor region and an anode contact
1-9. Positional relationship between a P+ type semiconductor region and an anode electrode
1-10. Power supply to the anode electrode
1-11. Action/effect
2. Second Embodiment
3. Third Embodiment
4. Fourth Embodiment
5. Fifth Embodiment
6. Sixth Embodiment
7. Seventh Embodiment
8. Eighth Embodiment
9. Ninth Embodiment
10. Other Embodiments
11. Example
11-1. Imaging device
11-2. Ranging device
12. Application example
13. Appendix

### 1. FIRST EMBODIMENT

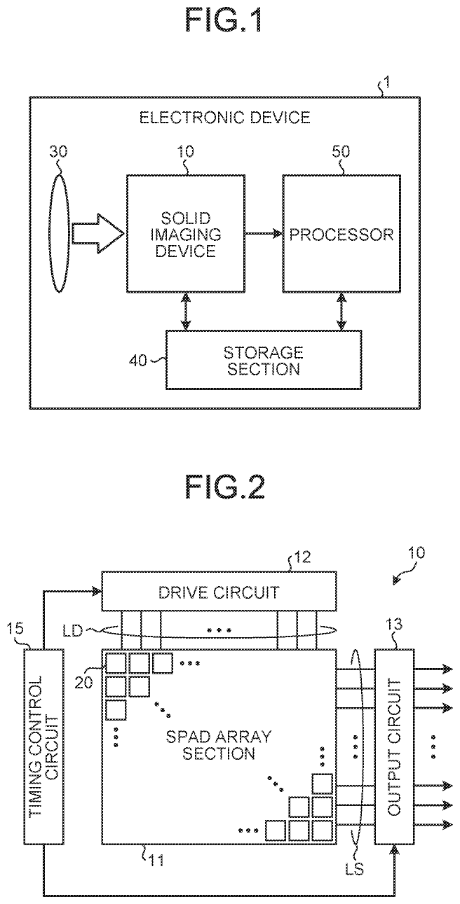

An electronic device 1 according to the first embodiment will be described with reference to FIG. 1 to FIG. 10.

### <1-1. Electronic Device>

FIG. 1 is a block diagram depicting a schematic configuration example of the electronic device 1 according to the first embodiment. As depicted in FIG. 1, the electronic device 1 includes, for example, an imaging lens 30, a solid imaging device 10, a storage section 40, and a processor (control section) 50.

The imaging lens 30 is an example of an optical system that collects incident light and forms an image thereof on a light receiving surface of the solid imaging device 10. The light receiving surface is, for example, a surface on which photoelectric conversion elements in the solid imaging device 10 are arrayed. The solid imaging device 10 photoelectrically converts the incident light and generates image data. Furthermore, the solid imaging device 10 executes predetermined signal processing such as a noise removal and a white balance adjustment on the generated image data.

The storage section 40 includes, for example, a flash memory, a dynamic random access memory (DRAM), a static random access memory (SRAM), or the like. The storage section 40 records the image data and the like input from the solid imaging device 10.

The processor 50 includes, for example, a central processing unit (CPU) or the like. The processor 50 may include an application processor that executes an operating system, various kinds of application software, and the like, a graphics processing unit (GPU), a baseband processor, or the like. With respect to the image data input from the solid imaging device 10, the image data read from the storage section 40, and the like, the processor 50 executes various kinds of processing as necessary, executes a display to the user, and performs transmission to the outside via a predetermined network.

### <1-2. Solid Imaging Device>

FIG. 2 is a block diagram depicting a schematic configuration example of a complementary metal-oxide-semiconductor (CMOS) type solid imaging device (image sensor) 10 according to the first embodiment. The CMOS type image sensor is an image sensor created by application or partial utilization of a CMOS process.

Note that in the present embodiment, as the solid imaging device 10, a so-called back-illuminated image sensor in which a surface opposite to an element formed surface in a semiconductor substrate is a light incident surface is described as an example. However, the solid imaging device 10 is not limited to the back-illuminated type. For example, a so-called front-illuminated type in which an element formed surface is a light incident surface can be also employed.

As depicted in FIG. 2, the solid imaging device 10 includes an SPAD array section 11, a drive circuit 12, an output circuit 13, and a timing control circuit 15.

The SPAD array section 11 includes a plurality of SPAD pixels 20 arrayed in a matrix. With respect to the plurality of SPAD pixels 20, a pixel drive line LD (line in a vertical direction in FIG. 2) is connected to each column, and an output signal line LS (line in a horizontal direction in FIG. 2) is connected to each row. One end of the pixel drive line LD is connected to an output end corresponding to each column of the drive circuit 12, and one end of the output signal line LS is connected to an input end corresponding to each row of the output circuit 13.

The drive circuit 12 includes a shift register, an address decoder, and the like, and drives all of the SPAD pixels 20 of the SPAD array section 11 at the same time, or performs driving thereof in units of columns, or the like. The drive circuit 12 includes at least a circuit that applies a quench voltage V_QCH to each of the SPAD pixels 20 in a selected column in the SPAD array section 11, and a circuit that applies a selection control voltage V_SEL to each of the SPAD pixels 20 in the selected column.

By applying the selection control voltage V_SEL to a pixel drive line LD corresponding to a column to be read, the drive circuit 12 selects the SPAD pixels 20, which are to be used for detection of incidence of photons, in units of columns. A signal output from each of the SPAD pixels 20 in the column selectively scanned by the drive circuit 12 (referred to as a detection signal) V_OUT is input to the output circuit 13 through each of the output signal lines LS. The output circuit 13 outputs the detection signal V_OUT, which is input from each of the SPAD pixels 20, as a pixel signal to the external storage section 40 or the processor 50.

The timing control circuit 15 includes a timing generator or the like that generates various timing signals. The timing control circuit 15 controls the drive circuit 12 and the output circuit 13 on the basis of the various timing signals generated by the timing generator.

### <1-3. SPAD Pixel>

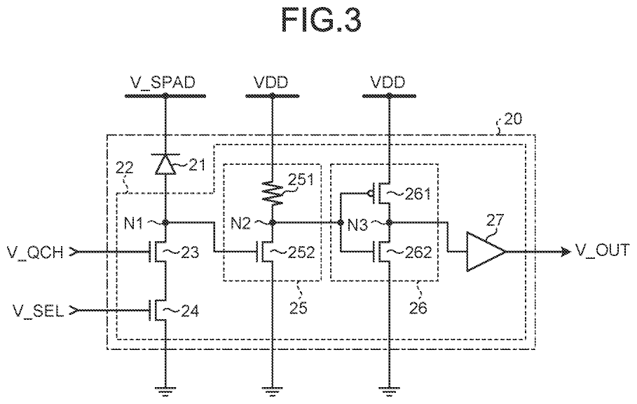

FIG. 3 is a circuit diagram depicting a schematic configuration example of an SPAD pixel 20 according to the first embodiment. As depicted in FIG. 3, the SPAD pixel 20 includes a photodiode 21 as a light receiving element, and a readout circuit 22 that detects incidence of a photon on the photodiode 21.

When a photon becomes incident on the photodiode 21 in a state in which a reverse bias voltage V_SPAD equal to or higher than a breakdown voltage (breakdown voltage) is applied between an anode and a cathode thereof, an avalanche current is generated.

The readout circuit 22 includes a quench resistor 23, a selection transistor 24, a digital converter 25, an inverter 26, and a buffer 27.

The quench resistor 23 includes, for example, an N type metal oxide semiconductor field effect transistor (MOSFET) (hereinafter, referred to as an NMOS transistor). A drain of the MOSFET included in the quench resistor 23 is connected to the anode of the photodiode 21, and a source thereof is grounded via the selection transistor 24. In addition, the quench voltage V_QCH is applied from the drive circuit 12 to a gate of the NMOS transistor included in the quench resistor 23 via the pixel drive line LD. The quench voltage V_QCH is previously set to cause the NMOS transistor to act as the quench resistor 23.

Note that the photodiode 21 is an SPAD in the present embodiment. The SPAD is an avalanche photodiode that operates in a Geiger mode when a reverse bias voltage equal to or higher than a breakdown voltage (breakdown voltage) is applied between an anode and a cathode thereof, and can detect incidence of one photon.

The selection transistor 24 is, for example, an NMOS transistor, a drain thereof being connected to the source of the NMOS transistor included in the quench resistor 23, and a source thereof being grounded. The selection transistor 24 is connected to the drive circuit 12, and changes from an OFF state to an ON state when the selection control voltage V_SEL from the drive circuit 12 is applied to a gate of the selection transistor 24 via the pixel drive line LD.

The digital converter 25 includes a resistor 251 and an NMOS transistor 252. A drain of the NMOS transistor 252 is connected to a power supply voltage VDD via the resistor 251, and a source thereof is grounded. In addition, a voltage at a connection point N1 between the anode of the photodiode 21 and the quench resistor 23 is applied to a gate of the NMOS transistor 252.

The inverter 26 includes a P type MOSFET (hereinafter, referred to as a PMOS transistor) 261 and an NMOS transistor 262. A drain of the PMOS transistor 261 is connected to the power supply voltage VDD, and a source thereof is connected to a drain of the NMOS transistor 262. The drain of the NMOS transistor 262 is connected to the source of the PMOS transistor 261, and a source thereof is grounded. A voltage at a connection point N2 between the resistor 251 and the drain of the NMOS transistor 252 is applied to each of a gate of the PMOS transistor 261 and a gate of the NMOS transistor 262. An output of the inverter 26 is input to the buffer 27.

The buffer 27 is a circuit for impedance conversion. When an output signal is input from the inverter 26, the buffer 27 performs impedance conversion on the input output signal, and outputs the converted signal as a detection signal V_OUT.

### <1-4. Schematic Operation Example of the SPAD Pixel>

The readout circuit 22 depicted as an example in FIG. 3 operates as follows, for example. First, during a period in which the selection control voltage V_SEL is applied from the drive circuit 12 to the selection transistor 24 and the selection transistor 24 is in the ON state, the reverse bias voltage V_SPAD equal to or higher than the breakdown voltage (breakdown voltage) is applied to the photodiode 21. As a result, operation of the photodiode 21 is permitted.

On the other hand, during a period in which the selection control voltage V_SEL is not applied from the drive circuit 12 to the selection transistor 24 and the selection transistor 24 is in the OFF state, the reverse bias voltage V_SPAD is not applied to the photodiode 21, whereby the operation of the photodiode 21 is prohibited.

When a photon becomes incident on the photodiode 21 when the selection transistor 24 is in the ON state, an avalanche current is generated in the photodiode 21. As a result, the avalanche current flows through the quench resistor 23, and the voltage at the connection point N1 increases. When the voltage at the connection point N1 becomes higher than an on-voltage of the NMOS transistor 252, the NMOS transistor 252 is brought into the ON state, and the voltage at the connection point N2 changes from the power supply voltage VDD to 0 V. When the voltage at the connection point N2 changes from the power supply voltage VDD to 0 V, the PMOS transistor 261 changes from the OFF state to the ON state, the NMOS transistor 262 changes from the ON state to the OFF state, and a voltage at a connection point N3 changes from 0 V to the power supply voltage VDD. As a result, the high-level detection signal V_OUT is output from the buffer 27.

Subsequently, when the voltage at the connection point N1 keeps increasing, the voltage applied between the anode and the cathode of the photodiode 21 becomes lower than the breakdown voltage. As a result, the avalanche current stops and the voltage at the connection point N1 decreases. Then, when the voltage at the connection point N1 becomes lower than the on-voltage of the NMOS transistor 252, the NMOS transistor 252 is brought into the OFF state, and the output of the detection signal V_OUT from the buffer 27 stops (low level).

As described above, the photon becomes incident on the photodiode 21 and the avalanche current is generated in the readout circuit 22. As a result, the high-level detection signal V_OUT is output during a period from the timing at which the NMOS transistor 252 is brought into the ON state to the timing at which the avalanche current stops and the NMOS transistor 252 is brought into the OFF state. The output detection signal V_OUT is input to the output circuit 13.

### <1-5. Layout Example of a Color Filter>

A color filter that selectively transmits light of a specific wavelength is arranged for the photodiode 21 of each of the SPAD pixels 20.

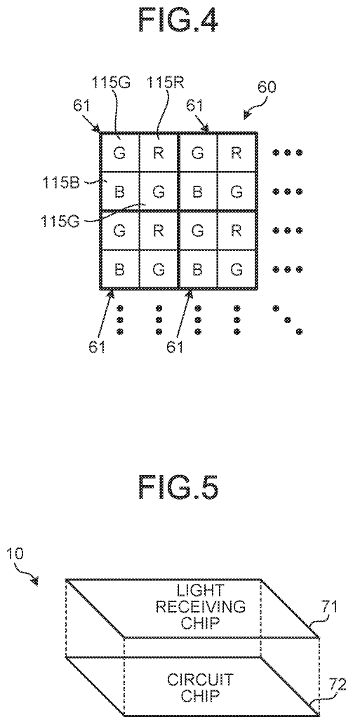

FIG. 4 is a diagram depicting a layout example of a color filter according to the first embodiment. As depicted in FIG. 4, a color filter array 60 has, for example, a configuration in which unit patterns 61 serving as units of repetition in a color filter array are arrayed in a two-dimensional lattice shape.

Each of the unit patterns 61 has, for example, a configuration of a so-called Bayer array including a total of four color filters that are a color filter 115R that selectively transmits light of a red (R) wavelength component, two color filters 115G that selectively transmit light of a green (G) wavelength component, and a color filter 115B that selectively transmits light of a blue (B) wavelength component.

Note that the color filter array 60 is not limited to the Bayer array in the present embodiment. For example, it is possible to employ various color filter arrays such as an X-Trans (registered trademark) type color filter array in which a unit pattern 61 is 3×3 pixels, a quad Bayer array of 4×4 pixels, and a white RGB type color filter array of 4×4 pixels including a color filter having a broad light transmission characteristic with respect to a visible light region (hereinafter, also referred to as clear or white) in addition to the color filters of the three primary colors of RGB.

### <1-6. Stacked Structure Example of the Solid Imaging Device>

FIG. 5 is a diagram depicting a stacked structure example of the solid imaging device 10 according to the first embodiment. As depicted in FIG. 5, the solid imaging device 10 has a structure in which a light receiving chip 71 and a circuit chip 72 are vertically stacked.

The light receiving chip 71 is, for example, a semiconductor chip including the SPAD array section 11 in which the photodiodes 21 are arrayed. The circuit chip 72 is, for example, a semiconductor chip on which the readout circuits 22 depicted in FIG. 3 are arrayed. Note that peripheral circuits such as the timing control circuit 15, the drive circuit 12, and the output circuit 13 may be arranged on the circuit chip 72.

For bonding of the light receiving chip 71 and the circuit chip 72, for example, so-called direct bonding in which bonded surfaces are flattened and are bonded to each other by force between electrons can be used. However, this is not a limitation, and for example, so-called Cu—Cu bonding in which copper (Cu) electrode pads formed on the bonded surfaces are bonded to each other, bump bonding, or the like can also be used.

In addition, the light receiving chip 71 and the circuit chip 72 are electrically connected via a connecting section such as a through-silicon via (TSV) penetrating the semiconductor substrate, for example. For the connection using the TSV, for example, a so-called twin TSV method in which two TSVs that are a TSV provided in the light receiving chip 71 and a TSV provided from the light receiving chip 71 to the circuit chip 72 are connected on outer surfaces of the chips, a so-called shared TSV method in which the both are connected by a TSV penetrating from the light receiving chip 71 to the circuit chip 72, or the like can be employed.

However, when Cu—Cu bonding or bump bonding is used for bonding of the light receiving chip 71 and the circuit chip 72, the both are electrically connected via a Cu—Cu bonding section or a bump bonding section.

### <1-7. Example of a Cross-Sectional Structure of the SPAD Pixel>

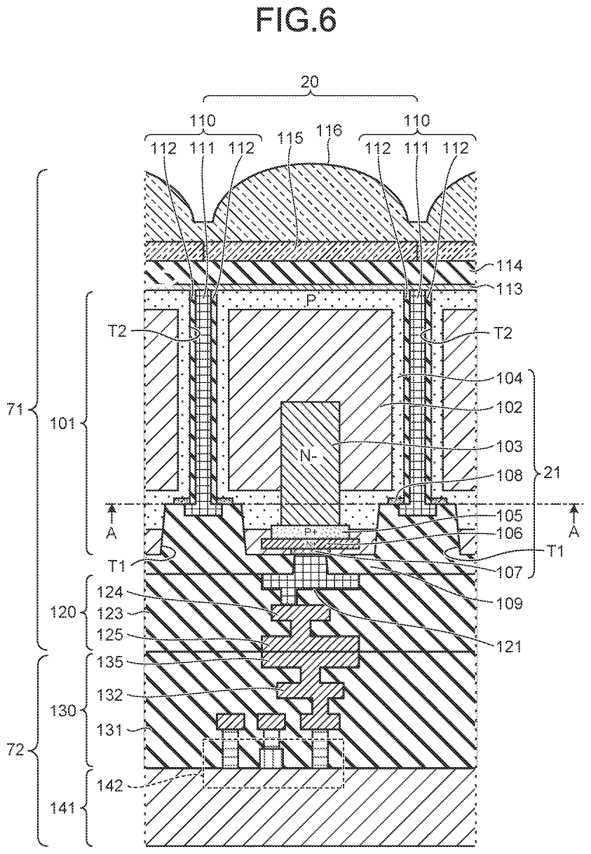

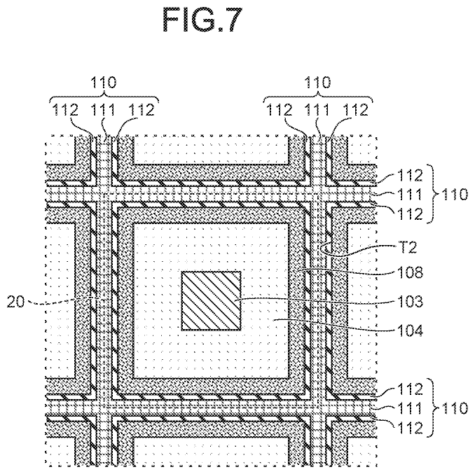

FIG. 6 is a vertical cross-sectional diagram depicting a cross-sectional structure example of a plane vertical to a light incident surface of the SPAD pixel 20 according to the first embodiment. FIG. 7 is a horizontal cross-sectional diagram depicting an example of the cross-sectional structure of an A-A plane in FIG. 6. Note that a focus is on a cross-sectional structure of the photodiode 21 in FIG. 6.

As depicted in FIG. 6, the photodiode 21 of the SPAD pixel 20 is provided, for example, on a semiconductor substrate 101 included in the light receiving chip 71. The semiconductor substrate 101 is partitioned into a plurality of element regions by, for example, an element isolation section (pixel isolation section) 110 having a lattice shape as viewed from a light incident surface (upper surface in FIG. 6) (see FIG. 7). The photodiode 21 is provided in each of the element regions partitioned by the element isolation section 110.

Each of the photodiodes 21 includes a photoelectric conversion region 102, a P type semiconductor region 104, an N− type semiconductor region 103, a P+ type semiconductor region 105, an N+ type semiconductor region 106, a cathode contact 107, and an anode contact 108.

Note that the P type semiconductor region 104 functions as a first semiconductor region, the P+ type semiconductor region 105 functions as a second semiconductor region, and the N+ type semiconductor region 106 functions as a third semiconductor region. In addition, the anode contact 108 functions as a first contact, and the cathode contact 107 functions as a second contact.

A photoelectric conversion region 102 is, for example, an N type well region or a region including a low concentration donor, and photoelectrically converts light incident from the light incident surface (hereinafter, referred to as incident light) and generates an electron-hole pair (hereinafter, referred to as a charge).

The N− type semiconductor region 103 is, for example, a region including a donor having higher concentration than the photoelectric conversion region 102. As depicted in FIG. 6 and FIG. 7, the N− type semiconductor region 103 is arranged in a central portion of the photoelectric conversion region 102, takes in a charge generated in the photoelectric conversion region 102, and guides the charge to the P+ type semiconductor region 105. Note that the N− type semiconductor region 103 is not an essential configuration, and may be omitted.

The P type semiconductor region 104 is, for example, a region including a P type acceptor, and is provided in a region surrounding the photoelectric conversion region 102 as depicted in FIG. 6 and FIG. 7. When the reverse bias voltage V_SPAD is applied to the anode contact 108 described later, the P type semiconductor region 104 forms an electric field to guide the charge generated in the photoelectric conversion region 102 to the N− type semiconductor region 103.

The P+ type semiconductor region 105 is, for example, a region including an acceptor having higher concentration than the P type semiconductor region 104, and a part thereof is in contact with the P type semiconductor region 104. Specifically, a back surface (upper surface in FIG. 6) that is a surface on a side of the light incident surface of the P+ type semiconductor region 105 is in contact with the P type semiconductor region 104 and the N-type semiconductor region 103.

The N+ type semiconductor region 106 is, for example, a region including a donor having concentration higher than that of the N− type semiconductor region 103, and is in contact with the P+ type semiconductor region 105. Specifically, a back surface (upper surface in FIG. 6) that is a surface on the side of the light incident surface of the N+ type semiconductor region 106 is in contact with the P+ type semiconductor region 105.

Such a P+ type semiconductor region 105 and N+type semiconductor region 106 function as regions that form a PN junction and form a multiplication section (multiplication region) that accelerates a charge, which flows in, and generates an avalanche current.

The cathode contact 107 is, for example, a region including a donor having concentration higher than that of the N+ type semiconductor region 106, and is in contact with the N+ type semiconductor region 106. Specifically, a back surface (upper surface in FIG. 6) that is a surface on the side of the light incident surface of the cathode contact 107 is in contact with the N+ type semiconductor region 106.

The anode contact 108 is, for example, a region including an acceptor having concentration higher than that of the P+ type semiconductor region 105. The anode contact 108 is provided in a region in contact with an outer periphery of the P type semiconductor region 104. A width of the anode contact 108 may be, for example, about 40 nanometers (nm). Since the anode contact 108 is made to be in contact along the outer periphery of the P type semiconductor region 104, a uniform electric field can be formed in the photoelectric conversion region 102.

Furthermore, as depicted in FIG. 6 and FIG. 7, the anode contact 108 is provided on a bottom surface (upper surface in FIG. 6) of a first trench T1. The first trench T1 is provided on a side of a front surface (lower surface in FIG. 6) of the semiconductor substrate 101 in such a manner that a shape viewed from the front surface is a lattice shape. By employment of such a bottom surface of the first trench T1, a formed position of the anode contact 108 is shifted in a height direction with respect to formed positions of the cathode contact 107 and the N+ type semiconductor region 106.

The side of the front surface (lower surface in FIG. 6) of the semiconductor substrate 101 is covered with an insulating film 109. A film thickness (thickness in a substrate width direction) of the insulating film 109 in the first trench T1 depends on a voltage value of the reverse bias voltage V_SPAD applied between the anode and the cathode, and may be about 150 nm, for example.

An opening to expose the cathode contact 107 placed on the front surface (lower surface in FIG. 6) of the semiconductor substrate 101 is provided in the insulating film 109. A cathode electrode 121 in contact with the cathode contact 107 is provided in the opening.

The element isolation section 110 is provided on the semiconductor substrate 101 in such a manner that a shape viewed from the light incident surface (upper surface in FIG. 6) is a lattice shape (see FIG. 7), and partitions the photodiodes 21. The element isolation section 110 is provided in the first trench T1 and a second trench T2 penetrating the semiconductor substrate 101 from the front surface (lower surface in FIG. 6) to the back surface (upper surface in FIG. 6). The second trench T2 is connected to the first trench T1 on the front surface side of the semiconductor substrate 101. An inner diameter of the second trench T2 is narrower than an inner diameter of the first trench T1. The anode contact 108 is formed in a stepped portion (bottom surface of the first trench T1) formed from the above.

The element isolation section 110 includes an insulating film 112 and an anode electrode 111. The insulating film 112 covers an inner side surface of the second trench T2. The anode electrode 111 is a metal layer that fills the first trench T1 and the second trench T2 covered with the insulating film 112, and is in contact with the anode contact 108 placed on the bottom surface of the first trench T1. The anode electrode 111 also functions as a light blocking film having a light blocking property. The anode electrode 111 functions as a first electrode.

Note that a film thickness (thickness in a substrate width direction) of the insulating film 112 depends on a voltage value of the reverse bias voltage V_SPAD applied between the anode and the cathode, and may be about 10 nm to 20 nm, for example. Furthermore, a film thickness (thickness in the substrate width direction) of the anode electrode 111 depends on a material or the like used for the anode electrode 111, and may be about 150 nm, for example.

As a conductive material having a light blocking property, for example, tungsten (W) or the like can be used. However, tungsten (W) is not a limitation, and various conductive materials having a property of reflecting or absorbing visible light or light necessary for each element, such as aluminum (Al), an aluminum alloy, and copper (Cu) can be used.

Here, the same conductive material may be used for the anode electrode 111 and the cathode electrode 121. In this case, the anode electrode 111 and the cathode electrode 121 can be collectively formed in the same process. However, there is a case where a material used for the cathode electrode 121 is not required to have the light blocking property, and a conductive material having no light blocking property may be used instead of the conductive material having the light blocking property.

The cathode electrode 121 protrudes from the front surface (lower surface in FIG. 6) of the insulating film 109. For example, a wiring layer 120 is provided on the front surface of the insulating film 109. The cathode electrode 121 functions as a second electrode.

The wiring layer 120 includes an interlayer insulating film 123, and a wiring line 124 provided in the interlayer insulating film 123. The wiring line 124 is in contact with, for example, the cathode electrode 121 protruding from the front surface (lower surface in FIG. 6) of the insulating film 109.

For example, a connection pad 125 made of copper (Cu) is exposed on the front surface (lower surface in FIG. 6) of the wiring layer 120. The connection pad 125 may be a part of the wiring line 124. In this case, the wiring line 124 is also made of copper (Cu).

For example, a connection pad 135 made of copper (Cu) is exposed on a back surface (upper surface in FIG. 6) of a wiring layer 130. The connection pad 135 may be a part of a wiring line 132. In this case, the wiring line 132 is also made of copper (Cu). By bonding (Cu—Cu bonding) of the connection pad 135 to the connection pad 125 exposed on the front surface of the wiring layer 120 of the light receiving chip 71, the light receiving chip 71 and the circuit chip 72 are electrically and mechanically connected.

The wiring layer 130 in the circuit chip 72 is bonded to the front surface (lower surface in FIG. 6) of the wiring layer 120. The wiring layer 130 includes an interlayer insulating film 131, and a wiring line 132 provided in the interlayer insulating film 131. The wiring line 132 is electrically connected to a circuit element 142 (such as readout circuit 22 and the like depicted in FIG. 3) formed on a semiconductor substrate 141. Thus, the cathode electrode 121 of the semiconductor substrate 101 is connected to the circuit element 142 via the wiring line 124, the connection pads 125 and 135, and the wiring line 132.

A pinning layer 113 and a flattening film 114 are provided on the back surface (upper surface in FIG. 6) of the semiconductor substrate 101. Furthermore, a color filter 115 and an on-chip lens 116 for each SPAD pixel 20 are provided on the flattening film 114.

The pinning layer 113 is, for example, a fixed charge film made of a hafnium oxide (HfO₂) film, an aluminum oxide (Al₂O₃) film, or the like including an acceptor of predetermined concentration.

The flattening film 114 is, for example, an insulating film made of an insulating material such as silicon oxide (SiO₂) or silicon nitride (SiN). The flattening film 114 is a film for flattening a surface on which the color filter 115 and the on-chip lens 116 on the upper layer are formed.

In the structure as described above, when the reverse bias voltage V_SPAD equal to or higher than the breakdown voltage is applied between the cathode contact 107 and the anode contact 108, an electric field that guides the charge generated in the photoelectric conversion region 102 to the N− type semiconductor region 103 is formed due to a potential difference between the P type semiconductor region 104 and the N+ type semiconductor region 106. In addition, in the PN junction region between the P+ type semiconductor region 105 and the N+ type semiconductor region 106, a strong electric field that generates an avalanche current by accelerating the entered charge is formed. As a result, operation of the photodiode 21 as an avalanche photodiode is permitted.

### <1-8. Positional Relationship Between an N+ Type Semiconductor Region and Anode Contact>

Next, a positional relationship between the N+ type semiconductor region 106 and the anode contact 108 will be described with reference to FIG. 6.

As depicted in FIG. 6, the anode contact 108 is arranged at the bottom of the first trench T1 formed on the front surface side of semiconductor substrate 101. As a result, the anode contact 108 is arranged at a position deeper than the front surface (lower surface in FIG. 6) of the semiconductor substrate 101 compared to the N+ type semiconductor region 106 (and the cathode contact 107). That is, in the present embodiment, in a case where the front surface of the semiconductor substrate 101 is used as a reference, a formed position of the anode contact 108 is shifted in a height direction with respect to a formed position of the N+ type semiconductor region 106.

In other words, a height of the anode contact 108 from the front surface of the semiconductor substrate 101 is different from a height of the N+ type semiconductor region 106 from the front surface of the semiconductor substrate 101. Specifically, the height of the anode contact 108 from the front surface of the semiconductor substrate 101 is higher than the height of the N+ type semiconductor region 106 from the front surface of the semiconductor substrate 101.

As described above, by shifting the formed position of the anode contact 108 and the formed position of the N+ type semiconductor region 106 (and the cathode contact 107) in the height direction, it is possible to increase a distance from the anode contact 108 to the N+type semiconductor region 106 (and/or the cathode contact 107) without increasing a size of the SPAD pixel 20 in a lateral direction (direction parallel to the incident surface). This makes it possible to control generation of the leakage current and the tunnel current without increasing a pixel size, whereby it is possible to stably generate avalanche amplification while controlling a decrease in resolution.

### <1-9. Positional Relationship Between a P+ Type Semiconductor Region and an Anode Electrode>

Next, a positional relationship between the P+ type semiconductor region 105 and the anode electrode 111 will be described with reference to FIG. 6.

As depicted in FIG. 6, one end of the anode electrode 111 which end is on the opposite side of the side of the light incident surface is placed on the side of the light incident surface compared to a contact surface (bonded surface) between the P+ type semiconductor region 105 and the N+ type semiconductor region 106 in the height direction. That is, a front surface (lower surface in FIG. 6) of the anode electrode 111 is placed on the side of the back surface (upper surface in FIG. 6) of the semiconductor substrate 101 compared to the contact surface between the P+ type semiconductor region 105 and the N+ type semiconductor region 106 in the height direction. In the example of FIG. 6, the front surface of the anode electrode 111 is placed on the side of the back surface of the semiconductor substrate 101 compared to a back surface of the P+ type semiconductor region 105 in the height direction.

In other words, a height of the front surface (lower surface in FIG. 6) of the anode electrode 111 from the front surface (lower surface in FIG. 6) of the semiconductor substrate 101 is higher than a height of the contact surface between the P+ type semiconductor region 105 and the N+ type semiconductor region 106 from the front surface of the semiconductor substrate 101. In the example of FIG. 6, the height of the front surface of the anode electrode 111 from the front surface of the semiconductor substrate 101 is higher than the height of the back surface (upper surface in FIG. 6) of the P+ type semiconductor region 105 from the front surface of the semiconductor substrate 101.

As described above, when the height of the front surface (lower surface in FIG. 6) of the anode electrode 111 from the front surface (lower surface in FIG. 6) of the semiconductor substrate 101 is made to be higher than the height of the contact surface between the P+ type semiconductor region 105 and the N+ type semiconductor region 106 from the front surface of the semiconductor substrate 101, metal having the same potential as the anode electrode 111 does not exist between the front surface of the semiconductor substrate 101 and the height of the contact surface between the P+ type semiconductor region 105 and the N+ type semiconductor region 106 in the element isolation section 110 (insulating film 109 in the first trench T1). As a result, a withstand voltage of the element isolation section 110 (insulating film 109 in the first trench T1) can be secured, and a change in the potential (potential) of the photodiode 21 can be controlled. Thus, a deformation of the multiplication section can be controlled, and deterioration in the multiplication characteristic and deterioration in the noise characteristic can be controlled.

### <1-10. Power Supply to the Anode Electrode>

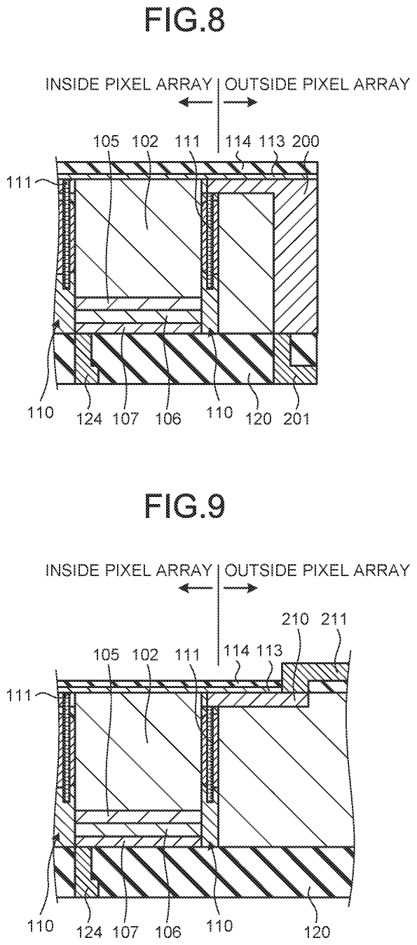

Next, power supply (first supply example and second supply example) from the side of the light incident surface of the SPAD pixel 20 to the anode electrode 111 will be described with reference to FIG. 8 and FIG. 9. FIG. 8 is a first diagram of assistance in explaining power supply from the side of the light incident surface of the SPAD pixel 20 to the anode electrode 111. FIG. 9 is a second diagram of assistance in explaining power supply from the side of light incident surface of the SPAD pixel 20 to the anode electrode 111. Note that portions unnecessary for the description related to the power supply are appropriately omitted in FIG. 8 and FIG. 9.

In the first supply example, as depicted in FIG. 8, a contact layer 200 is provided outside a pixel array (pixel array region). The contact layer 200 is placed on the back surface (upper surface in FIG. 8) of the wiring layer 120, and extends from a side of the front surface (lower surface in FIG. 8) to the side of the light incident surface, which is the back surface, along the element isolation section 110. One end of the contact layer 200 is in contact with a wiring line 201 provided in the wiring layer 120. The other end of the contact layer 200 is in contact with the anode electrode 111. As a result, electric connection from the side of the front surface to the side of the light incident surface that is the back surface is realized with respect to the anode electrode 111 outside the pixel array, and voltage is supplied to the anode electrode 111 that is a lattice-shaped metal layer.

In the second supply example, as depicted in FIG. 9, a contact layer 210 is provided outside the pixel array (pixel array region). The contact layer 210 is provided on the back surface (upper surface in FIG. 9) of the semiconductor substrate 101 (see FIG. 6), and extends toward the outside of the pixel array along the back surface. One end of the contact layer 210 is provided on the back surface of the semiconductor substrate 101 and is in contact with a wiring line 211. The other end of the contact layer 210 is in contact with the anode electrode 111. As a result, electric connection from the side of the light incident surface is realized with respect to the anode electrode 111 outside the pixel array, and voltage is supplied to the anode electrode 111 that is a lattice-shaped metal layer.

Note that in FIG. 8 and FIG. 9, the contact layer 200 or the contact layer 210 is provided outside the pixel array. However, this is not a limitation and the contact layer 200 or the contact layer 210 may be provided in the pixel array. For example, one pixel in the pixel array (for example, an endmost pixel in the pixel array) may not be used as a pixel, the contact layer 200 or the contact layer 210 may be provided in the pixel, and voltage may be supplied to the anode electrode 111 that is the lattice-shaped metal layer.

Furthermore, the anode electrode 111 is continuous in the plurality of SPAD pixels 20 (see FIG. 7). For example, all the SPAD pixels 20 arrayed in the SPAD array section 11 are electrically connected. Thus, a configuration in which the contact layer 200 or 210 is provided in a one-to-one manner with respect to the anode electrode 111 of each of the SPAD pixels 20 is not essential.

For example, the contact layer 200 or 210 may be provided for at least one of the SPAD pixels 20 placed at an outermost periphery of the SPAD array section 11, and the contact layer 200 or 210 may not be provided for the other SPAD pixels 20. Alternatively, the contact layer 200 or 210 may be provided for every predetermined number of the SPAD pixels 20. As described above, since a wiring pattern can be simplified by reduction of the contact layers 200 and 210, simplification of a manufacturing process, reduction in a manufacturing cost, and the like can be realized.

### <1-11. Action/Effect>

As described above, in the first embodiment, the position of the anode contact 108 and the position of the cathode contact 107 and/or the N+ type semiconductor region 106 are shifted in the height direction. This makes it possible to increase the distance from the anode contact 108 to the cathode contact 107 and/or the N+ type semiconductor region 106 without increasing the size of the SPAD pixel 20 in the lateral direction (direction parallel to the incident surface). As a result, it becomes possible to control generation of the leakage current and the tunnel current without increasing the pixel size, whereby it is possible to stably generate avalanche amplification while controlling a decrease in resolution.

Furthermore, in the first embodiment, one end of the anode electrode 111 that is the metal layer, the one end being on the opposite side of the side of the light incident surface, is placed on the side of the light incident surface compared to the contact surface between the P+ type semiconductor region 105 and the N+ type semiconductor region 106 in the height direction. As a result, in the element isolation section 110 (insulating film 109 in the first trench T1), metal having the same potential as the anode electrode 111 does not exist between the surface opposite to the light incident surface and the height of the contact surface between the P+ type semiconductor region 105 and the N+ type semiconductor region 106. Thus, the withstand voltage of the element isolation section 110 (insulating film 109 in the first trench T1) can be secured, and a change in the potential (potential) of a side of the photodiode 21 (Si side) can be controlled. Thus, a deformation of the multiplication section can be controlled, and deterioration in the multiplication characteristic and deterioration in the noise characteristic can be controlled.

Note that although a so-called front full trench isolation (FFTI) type element isolation section 110 in which the second trench T2 penetrates the semiconductor substrate 101 from the front surface side is described as an example in the first embodiment, this is not a limitation. For example, it is also possible to employ an FTI type element isolation section in which a second trench T2 penetrates a semiconductor substrate 101 from a back surface side, or a deep trench isolation (DTI) type element isolation section in which a second trench T2 is formed from a front surface to the middle of the semiconductor substrate 101. In a case of the FTI type in which the second trench T2 penetrates the semiconductor substrate 101 from the back surface side, a material of an anode electrode 111 may be embedded in the second trench T2 from the back surface side of the semiconductor substrate 101.

In addition, in the first embodiment, a case where the cathode is the N type and the anode is the P type has been described as an example. However, such a combination is not a limitation, and various modifications such as a cathode being the P type and an anode being the N type can be made.

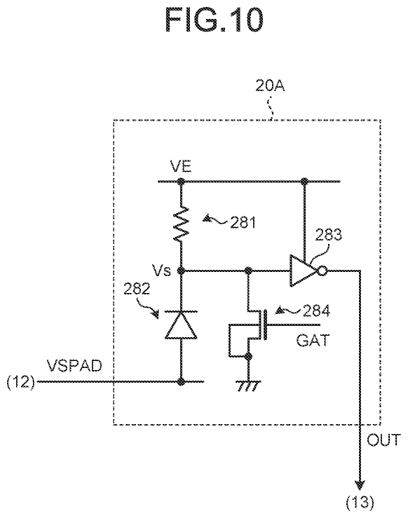

Furthermore, in the first embodiment, the schematic configuration example of the SPAD pixel 20 depicted in FIG. 3 has been described as an example. However, this is not a limitation, and, for example, a schematic configuration of an SPAD pixel 20A depicted in FIG. 10 can also be employed. FIG. 10 is a circuit diagram depicting another schematic configuration example of the SPAD pixel 20 according to the first embodiment, that is, a schematic configuration example of the SPAD pixel 20A.

As depicted in FIG. 10, the SPAD pixel 20A includes a resistor 281, a photodiode 282, an inverter 283, and a transistor 284. One end of the resistor 281 is connected to a cathode of the photodiode 282, and the other end of the resistor 281 is connected to a terminal of a potential VE. As the transistor 284, for example, an N type metal oxide semiconductor (MOS) transistor is used. A gate signal GAT of a predetermined potential is applied to a gate of the transistor 284. A source of the transistor 284 is connected to a back gate and a ground terminal, and a drain is connected to the cathode of the photodiode 282 and an input terminal of the inverter 283. For example, a low level is set to the gate signal GAT in a row reading period.

When light is incident, the photodiode 282 photoelectrically converts the incident light and outputs a photocurrent Im. An SPAD is used as the photodiode 282. An anode potential VSPAD of the photodiode 282 is controlled by the drive circuit 12. The inverter 283 inverts a signal of a cathode potential Vs of the photodiode 282 and outputs the inverted signal to an output circuit 13 as a pulse signal OUT. The inverter 283 outputs the low-level pulse signal OUT in a case where the cathode potential Vs is higher than a predetermined threshold, and outputs the high-level pulse signal OUT in a case where the cathode potential Vs is equal to or lower than the threshold.

When light is incident on the photodiode 282, the photocurrent Im from the photodiode 282 flows through the resistor 281, and the cathode potential Vs drops according to a current value thereof. When the cathode potential Vs at the time of the drop is equal to or lower than the threshold, the inverter 283 outputs the high-level pulse signal OUT. Thus, the output circuit 13 can detect a rising timing of the pulse signal OUT as a light receiving timing.

### 2. SECOND EMBODIMENT

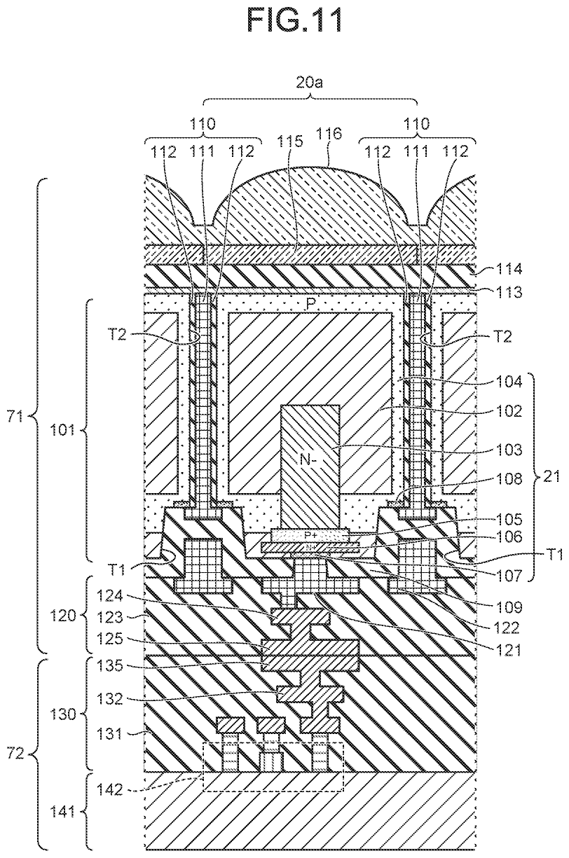

Next, an SPAD pixel 20a according to the second embodiment will be described with reference to FIG. 11. FIG. 11 is a vertical cross-sectional diagram depicting a cross-sectional structure example of a plane vertical to a light incident surface of the SPAD pixel 20a according to the second embodiment. Hereinafter, differences from the first embodiment will be mainly described, and description of the others will be omitted.

As depicted in FIG. 11, the SPAD pixel 20a according to the second embodiment includes a metal section 122 having a light blocking property in addition to the sections according to the first embodiment. The metal section 122 is provided on a front surface (lower surface in FIG. 11) of an insulating film 109 and in an element isolation section 110. For example, the metal section 122 is provided in a first trench T1 in such a manner as to face an anode electrode 111, and is formed in such a manner that a shape viewed from a light incident surface (upper surface in FIG. 11) is a lattice shape. The metal section 122 extends from the front surface of the insulating film 109 toward the anode electrode 111 to a position that is not in contact with the anode electrode (non-contact position) 111. An insulating film 109 exists between the anode electrode 111 and the metal section 122, and the anode electrode 111 and the metal section 122 are insulated. The metal section 122 and the anode electrode 111 may be formed of the same metal material or different metal materials.

One end of the metal section 122 which end is on a side of the light incident surface is placed on the side of the light incident surface compared to a contact surface between a P+ type semiconductor region 105 and an N+ type semiconductor region 106 in a height direction. That is, a back surface (upper surface in FIG. 11) of the metal section 122 is placed on a side of a back surface (upper surface in FIG. 11) of a semiconductor substrate 101 compared to the contact surface between the P+ type semiconductor region 105 and the N+ type semiconductor region 106 in the height direction. In other words, a height of the back surface (upper surface in FIG. 11) of the metal section 122 from the front surface (lower surface in FIG. 11) of the semiconductor substrate 101 is higher than a height of the contact surface between the P+ type semiconductor region 105 and the N+ type semiconductor region 106 from the front surface of the semiconductor substrate 101.

As described above, according to the second embodiment, by providing the metal section 122 that is not in contact with the anode electrode 111 in the first trench T1, it is possible to reduce a required withstand voltage of the element isolation section 110 (insulating film 109 in the first trench T1). Thus, it is possible to reliably control a change in a potential on a side of a photodiode 21 (Si side). Thus, a deformation of a multiplication section can be controlled, and deterioration in a multiplication characteristic and a noise characteristic can be reliably controlled. Furthermore, since light (such as incident light, reflected light, or the like) directed to an adjacent SPAD pixel 20a can be blocked by the metal section 122, crosstalk resistance can be improved, and deterioration in the noise characteristic can be controlled. Note that effects similar to those of the first embodiment can be also acquired in the second embodiment.

Furthermore, one end of the metal section 122 which end is on the side of the light incident surface is placed on the side of the light incident surface compared to the contact surface between the P+ type semiconductor region 105 and the N+ type semiconductor region 106 in the height direction. As a result, light directed to the adjacent SPAD pixel 20a can be reliably blocked by the metal section 122, whereby the crosstalk resistance can be further improved, and the deterioration in the noise characteristic can be reliably controlled.

### 3. THIRD EMBODIMENT

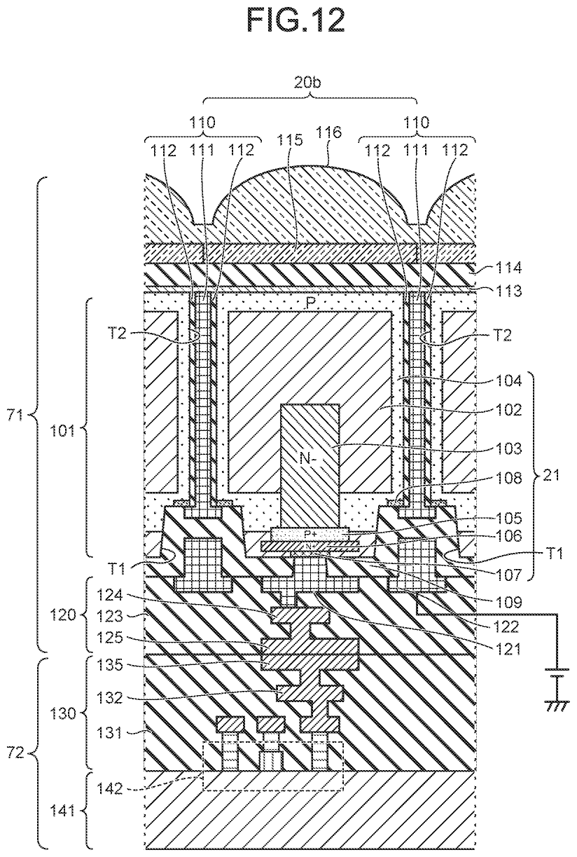

Next, an SPAD pixel 20b according to the third embodiment will be described with reference to FIG. 12. FIG. 12 is a vertical cross-sectional diagram depicting a cross-sectional structure example of a plane vertical to a light incident surface of the SPAD pixel 20b according to the third embodiment. Hereinafter, differences from the second embodiment will be mainly described, and description of the others will be omitted.

As depicted in FIG. 12, in the SPAD pixel 20b according to the third embodiment, a predetermined voltage is applied to a metal section 122. By using the voltage applied to the metal section 122, a potential (potential) on a side of a photodiode 21 (Si side) can be modulated. It is assumed that the voltage applied to the metal section 122 is V1, a voltage applied to an anode electrode 111 is V2, and a voltage applied to a cathode electrode 121 is V3. When each voltage is supplied in a relationship of V2<V1<V3, a deformation controlling effect of a multiplication section (multiplication region) is enhanced, and it is possible to assist a transfer to a cathode contact 107 without multiplying electrons of a dark current generated in an element isolation section 110 (side wall). On the other hand, when each voltage is supplied in a relationship of V1<V2, it is possible to induce holes by the voltage, to form pinning, and to control generation of electrons.

As described above, according to the third embodiment, by appropriately adjusting magnitudes of the voltage applied to the metal section 122, the voltage applied to the anode electrode 111, and the voltage applied to the cathode electrode 121, for example, by performing setting on the basis of a predetermined relational expression, it is possible to reliably control deterioration in a multiplication characteristic and deterioration in a noise characteristic. Note that effects similar to those of the first and second embodiments can be also acquired in the third embodiment.

### 4. Fourth Embodiment

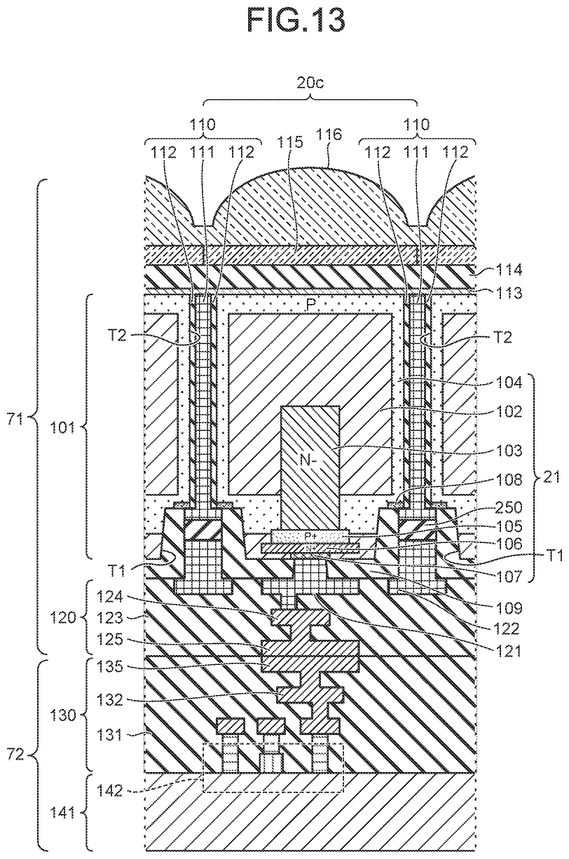

Next, an SPAD pixel 20c according to the fourth embodiment will be described with reference to FIG. 13. FIG. 13 is a vertical cross-sectional diagram depicting a cross-sectional structure example of a plane vertical to a light incident surface of the SPAD pixel 20c according to the fourth embodiment. Hereinafter, differences from the second embodiment will be mainly described, and description of the others will be omitted.

As depicted in FIG. 13, in the SPAD pixel 20c according to the fourth embodiment, an insulating film 250 having a light blocking property is provided between an anode electrode 111 and a metal section 122. Examples of the insulating film 250 having the light blocking property include a color filter. For example, in adjacent SPAD pixels 20c, a color filter different from colors of those pixels is used as the insulating film 250. For example, in a case where the colors of pixels are green and blue in the adjacent SPAD pixels 20c, a red color filter is used as the insulating film 250.

As described above, according to the fourth embodiment, by providing the insulating film 250 having the light blocking property between the anode electrode 111 and the metal section 122, it becomes possible to block light (such as incident light, reflected light, or the like) directed to the adjacent SPAD pixels 20c with the insulating film 250 in addition to the metal section 122, whereby crosstalk resistance can be improved and deterioration in a noise characteristic can be controlled. Note that effects similar to those of the first and second embodiments can be also acquired in the fourth embodiment.

According to the fourth embodiment, the insulating film 250 having the light blocking property is provided between the anode electrode 111 and the metal section 122. However, this is not a limitation, and a gas layer having a light blocking property and an insulating property may be provided as the insulating film 250 having the light blocking property. Examples of the gas layer include an air layer.

In addition, according to the fourth embodiment, a predetermined voltage is not applied to the metal section 122 that is not in contact with the anode electrode 111. However, this is not a limitation, and the predetermined voltage may be applied to the metal section 122 as in the third embodiment. In this case, effects similar to those of the third embodiment can be acquired.

### 5. FIFTH EMBODIMENT

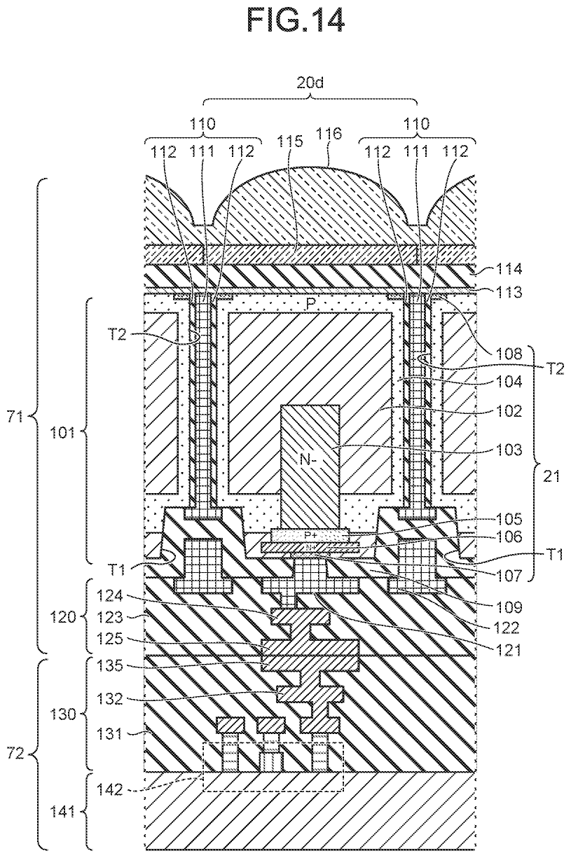

Next, an SPAD pixel 20d according to the fifth embodiment will be described with reference to FIG. 14. FIG. 14 is a vertical cross-sectional diagram depicting a cross-sectional structure example of a plane vertical to a light incident surface of the SPAD pixel 20d according to the fifth embodiment. Hereinafter, differences from the second embodiment will be mainly described, and description of the others will be omitted.

As depicted in FIG. 14, in the SPAD pixel 20d according to the fifth embodiment, an anode contact 108 is provided on a side of a light incident surface (back surface contact). As a result, there is a degree of freedom at a position where an anode electrode 111 and a metal section 122 are isolated. In a case of such a configuration, the configuration does not need to be an FFTI type (DTI type and FTI type), and a configuration only including the FTI type may be employed.

As described above, according to the fifth embodiment, the anode contact 108 is provided on the side of the light incident surface of the SPAD pixel 20d, whereby a degree of freedom is given to a position at which the anode electrode 111 and the metal section 122 are separated, and an isolation position can be determined in consideration of a balance between crosstalk and a potential (potential) on the side of a photodiode 21 (Si side). However, from a viewpoint of the potential, since a large voltage drop starts to be generated, it is desirable to place the isolation position around a side of a P+ type semiconductor region 105 that forms a multiplication section (multiplication region). Note that effects similar to those of the first and second embodiments can be also acquired in the fifth embodiment.

According to the fifth embodiment, a predetermined voltage is not applied to the metal section 122 that is not in contact with the anode electrode 111. However, this is not a limitation, and the predetermined voltage may be applied to the metal section 122 as in the third embodiment. In this case, effects similar to those of the third embodiment can be acquired.

### 6. SIXTH EMBODIMENT

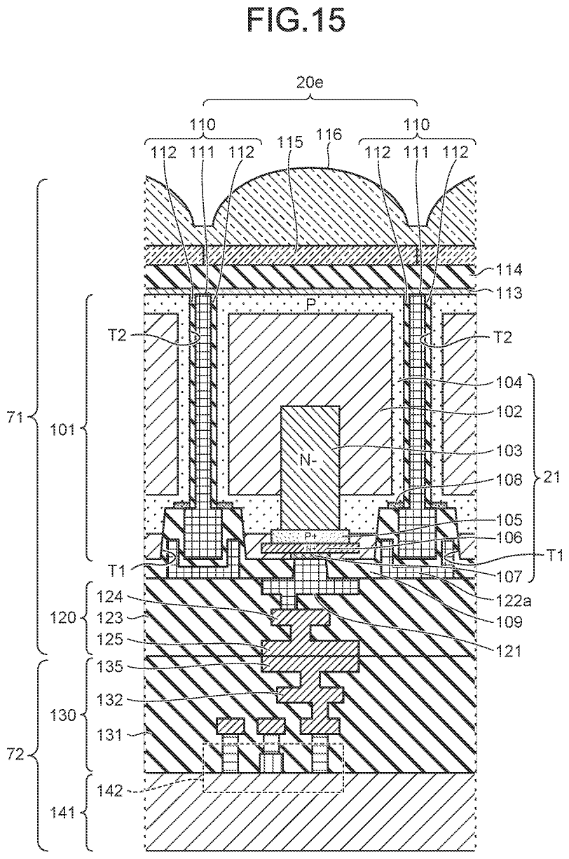

Next, an SPAD pixel 20e according to the sixth embodiment will be described with reference to FIG. 15. FIG. 15 is a vertical cross-sectional diagram depicting a cross-sectional structure example of a plane vertical to a light incident surface of the SPAD pixel 20e according to the sixth embodiment. Hereinafter, differences from the first embodiment will be mainly described, and description of the others will be omitted.

As depicted in FIG. 15, in the SPAD pixel 20e according to the sixth embodiment, one end of an anode electrode 111 which end is on an opposite side of a side of a light incident surface is placed on the opposite side of the side of the light incident surface compared to a contact surface between a P+ type semiconductor region 105 and an N+ type semiconductor region 106 in a height direction. That is, a front surface (lower surface in FIG. 15) of the anode electrode 111 is placed on a side of a front surface (lower surface in FIG. 15) of a semiconductor substrate 101 compared to the contact surface between the P+ type semiconductor region 105 and the N+ type semiconductor region 106 in the height direction. In the example of FIG. 15, the front surface of the anode electrode 111 is placed on the side of the front surface of the semiconductor substrate 101 compared to a front surface of the N+ type semiconductor region 106 in the height direction.

In other words, a height of the front surface (lower surface in FIG. 15) of the anode electrode 111 from the front surface (lower surface in FIG. 15) of the semiconductor substrate 101 is lower than a height of the contact surface between the P+ type semiconductor region 105 and the N+ type semiconductor region 106 from the front surface of the semiconductor substrate 101. In the example of FIG. 15, the height of the front surface of the anode electrode 111 from the front surface of the semiconductor substrate 101 is lower than a height of the front surface (lower surface in FIG. 15) of the N+ type semiconductor region 106 from the front surface of the semiconductor substrate 101.

In addition, the SPAD pixel 20e according to the sixth embodiment includes a metal section 122a having a light blocking property in addition to the sections according to the first embodiment. The metal section 122a is provided on a front surface (lower surface in FIG. 15) of an insulating film 109 and in an element isolation section 110. For example, the metal section 122a is provided in a first trench T1 in such a manner as to face the anode electrode 111, and is formed in such a manner that a shape viewed from the light incident surface (upper surface in FIG. 15) is a lattice shape.

The metal section 122a is formed in a shape that covers one end of the anode electrode 111 which end is on the opposite side of the side of the light incident surface, and that sandwiches the anode electrode 111 without being in contact with the anode electrode 111 (such as U shape). That is, a part of the metal section 122a extends from the front surface (lower surface in FIG. 6) of the semiconductor substrate 101 toward the light incident surface, and is placed between the P+ type semiconductor region 105 and the N+ type semiconductor region 106 and the anode electrode 111. Note that although being formed in a U shape, a shape of the metal section 122a is not limited thereto and may be formed in various shapes such as a plate shape and an L shape.

As described above, according to the sixth embodiment, by providing the metal section 122a that is not in contact with the anode electrode 111 in the first trench T1, it is possible to adjust a withstand voltage of an element isolation section 110 (insulating film 109 in the first trench T1) and reduce the required withstand voltage of the element isolation section 110, whereby it is possible to control a change in a potential on a side of a photodiode 21 (Si side). Thus, a deformation of a multiplication section can be controlled, and deterioration in a multiplication characteristic and a noise characteristic can be controlled. Furthermore, since light (such as incident light, reflected light, or the like) directed to an adjacent SPAD pixel 20a can be blocked by the metal section 122a, crosstalk resistance can be improved, and deterioration in the noise characteristic can be controlled. Note that effects similar to those of the first embodiment can be also acquired in the second embodiment.

According to the sixth embodiment, the one end of the metal section 122a which end is on the side of the light incident surface is placed on the side of the light incident surface compared to the contact surface between the P+ type semiconductor region 105 and the N+ type semiconductor region 106 in the height direction. However, this is not a limitation, and one end may be placed on an opposite side of the side of the light incident surface compared to the contact surface between the P+ type semiconductor region 105 and the N+ type semiconductor region 106.

In addition, according to the sixth embodiment, a predetermined voltage is not applied to the metal section 122a that is not in contact with the anode electrode 111. However, this is not a limitation, and the predetermined voltage may be applied to the metal section 122a as in the third embodiment. In this case, effects similar to those of the third embodiment can be acquired.

### 7. SEVENTH EMBODIMENT

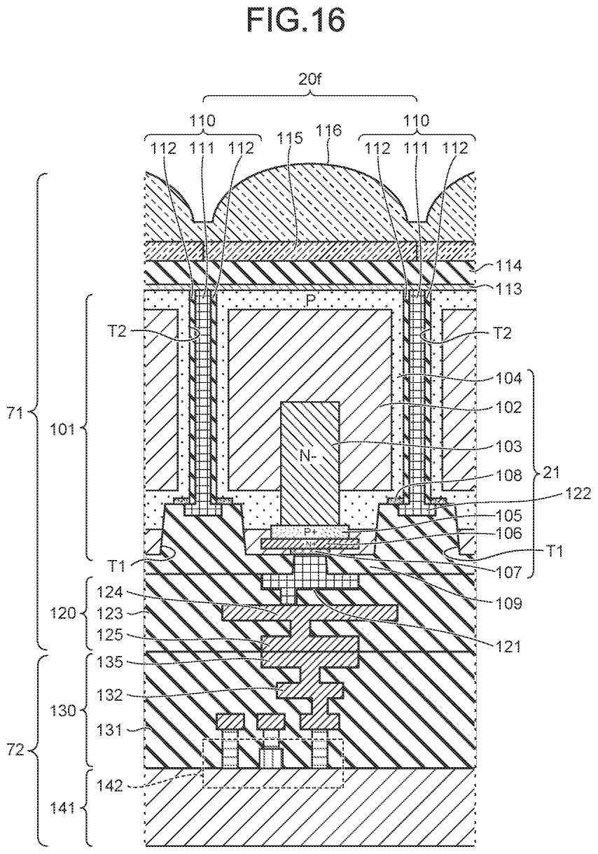

Next, an SPAD pixel 20f according to the seventh embodiment will be described with reference to FIG. 16. FIG. 16 is a vertical cross-sectional diagram depicting a cross-sectional structure example of a plane vertical to a light incident surface of the SPAD pixel 20f according to the seventh embodiment. Hereinafter, differences from the first embodiment will be mainly described, and description of the others will be omitted.

As depicted in FIG. 16, in the SPAD pixel 20f according to the seventh embodiment, a wiring line 124 is formed to be wider than a contact surface between a P+ type semiconductor region 105 and an N+ type semiconductor region 106 in such a manner as to cover the contact surface. That is, the SPAD pixel 20f is formed to have a reflection structure in which surfaces other than the light incident surface is surrounded by an anode electrode 111 and the wiring line 124. As a result, light is reflected by the anode electrode 111 and the wiring line 124, and sensitivity can be improved while generation of crosstalk is controlled.

As described above, according to the seventh embodiment, light passing through the SPAD pixel 20f can be reflected to a side of a photodiode 21 by the wiring line 124, whereby the sensitivity of the SPAD pixel 20f can be improved. Note that effects similar to those of the first embodiment can be also acquired in the seventh embodiment.

### 8. EIGHTH EMBODIMENT

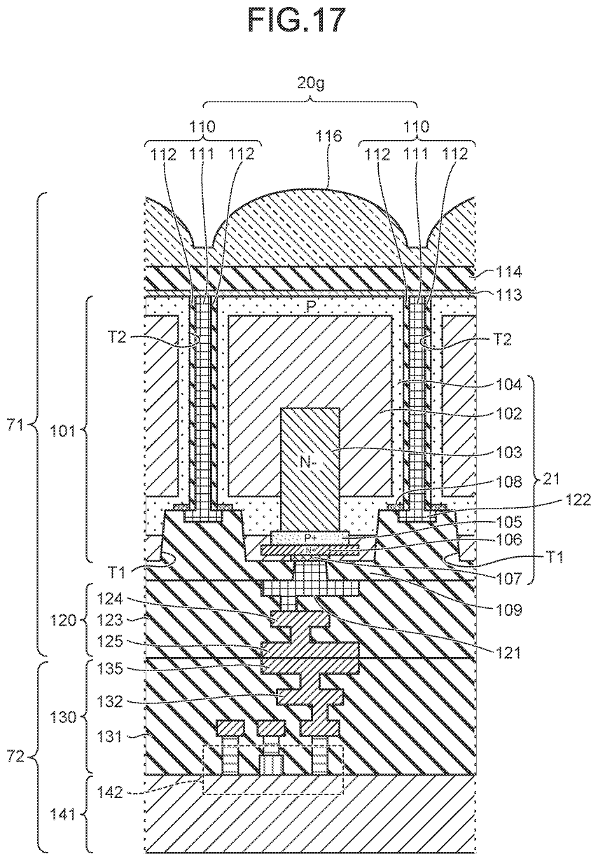

Next, an SPAD pixel 20g according to the eighth embodiment will be described with reference to FIG. 17. FIG. 17 is a vertical cross-sectional diagram depicting a cross-sectional structure example of a plane vertical to a light incident surface of the SPAD pixel 20g according to the eighth embodiment. Hereinafter, differences from the first embodiment will be mainly described, and description of the others will be omitted.

As depicted in FIG. 17, the SPAD pixel 20g has a structure in which a color filter 115 is omitted in a structure similar to a cross-sectional structure described with reference to FIG. 6 and the like in the first embodiment. The SPAD pixel 20g is used, for example, in a ranging device that measures a distance to an object. Note that the color filter 115 may be omitted in the other embodiments.

As described above, according to the eighth embodiment, the SPAD pixel 20g can be used for the ranging device by omission of the color filter 115 as in the SPAD pixel 20g. Note that effects similar to those of the first embodiment can be also acquired in the eighth embodiment.

### 9. NINTH EMBODIMENT

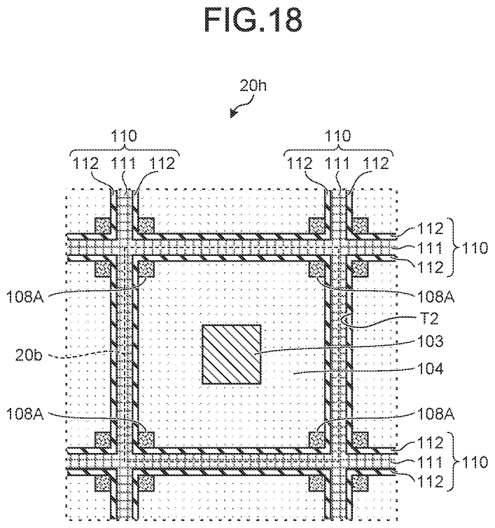

Next, an SPAD pixel 20h according to the ninth embodiment will be described with reference to FIG. 18. FIG. 18 is a horizontal cross-sectional diagram depicting a cross-sectional structure example of a plane parallel to a light incident surface of an SPAD pixel 20h according to the ninth embodiment. Note that the plane in FIG. 18 corresponds to the plane in FIG. 7.

As depicted in FIG. 18, in the SPAD pixel 20h according to the ninth embodiment, in a structure similar to the cross-sectional structure described with reference to FIG. 7 and the like in the first embodiment, a formed region of an anode contact 108A is limited to be in contact with a P type semiconductor region 104 at a part of an outer periphery of the P type semiconductor region 104. In the specific example depicted in FIG. 18, the formed region of the anode contact 108A is limited to four corners of a rectangular region partitioned by an element isolation section 110.

As described above, according to the ninth embodiment, a contact portion between an anode contact 108 and an anode electrode 111 can be controlled by limitation of the formed region of the anode contact 108A. Thus, for example, a distribution of an electric field formed in a photoelectric conversion region 102 can be controlled.

### 10. OTHER EMBODIMENTS

Note that an insulating film 112 in a second trench T2 may be omitted in a structure similar to a cross-sectional structure described with reference to FIG. 6 and the like in the first embodiment. In such a manner, by omission of the insulating film 112 in an element isolation section 110, an anode electrode 111 and a P type semiconductor region 104 can be made to be contact with each other not only in an anode contact 108 but also in the second trench T2, whereby it is possible to realize a contact with low resistance.

In addition, in a structure similar to the cross-sectional structure described with reference to FIG. 6 and the like in the first embodiment, a P+ type semiconductor region 105 and an N+ type semiconductor region 106 may extend to be in contact with an insulating film 109 formed in a first trench T1. In such a manner, by expanding the P+ type semiconductor region 105 and the N+ type semiconductor region 106 to an entire region sandwiched by the first trench T1, it becomes possible to expand a region where avalanche amplification is generated, whereby quantum efficiency can be improved. In addition, by expanding the P+ type semiconductor region 105 to the entire region sandwiched by the first trench T1, a charge generated near the anode contact 108 can be prevented from directly flowing into the N+ type semiconductor region 106 or a cathode contact 107, whereby it becomes possible to reduce the charge that does not contribute to avalanche amplification and to improve the quantum efficiency.

In addition, in a structure similar to the cross-sectional structure described with reference to FIG. 6 and the like in the first embodiment, a diameter of a first trench T1 may be increased and an insulating film 109 in the first trench T1 may be expanded to a degree of being in contact with at least a P+ type semiconductor region 105. As described above, by increasing the diameter of the first trench T1 and making the insulating film 109 to be in contact with the P+ type semiconductor region 105, it is possible to prevent a charge generated near an anode contact 108 from directly flowing into an N+ type semiconductor region 106 or a cathode contact 107, whereby it is possible to reduce the charge that does not contribute to avalanche amplification and to improve quantum efficiency.

### 11. EXAMPLE

The solid imaging device 10 described above can be applied to various electronic devices such as imaging devices such as a digital still camera and a digital video camera, a mobile phone having an imaging function, and other devices having an imaging function.

### <11-1. Imaging Device>

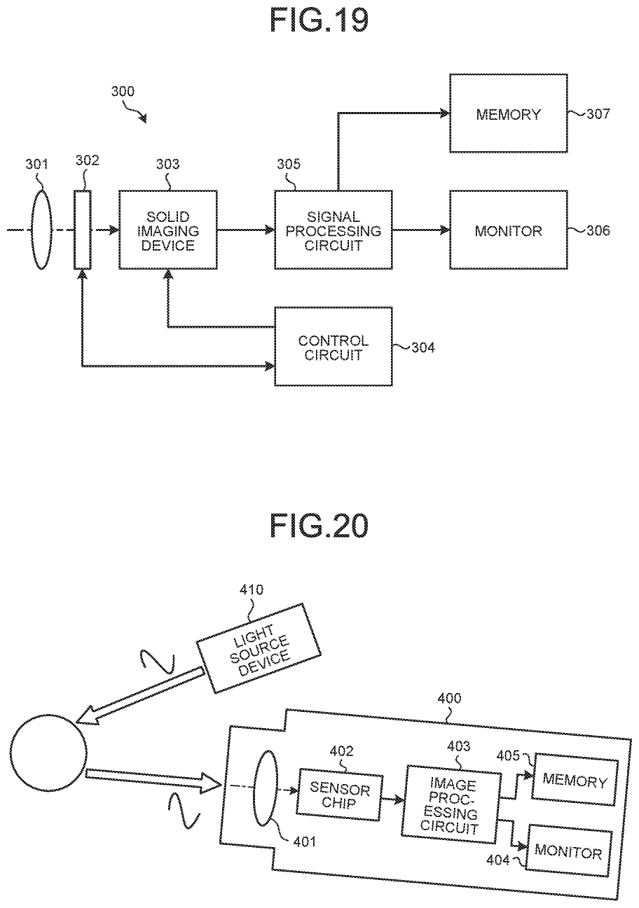

An imaging device 300 will be described with reference to FIG. 19. FIG. 19 is a block diagram depicting a configuration example of the imaging device 300 as an electronic device to which the present technology is applied.

As depicted in FIG. 19, the imaging device 300 includes an optical system 301, a shutter device 302, a solid imaging device (individual imaging element) 303, a control circuit (drive circuit) 304, a signal processing circuit 305, a monitor 306, and a memory 307. The imaging device 300 can capture a still image and a moving image.

The optical system 301 includes one or a plurality of lenses. The optical system 301 guides light (incident light) from a subject to the solid imaging device 303 and forms an image on a light receiving surface of the solid-state imaging device 303.

The shutter device 302 is arranged between the optical system 301 and the solid imaging device 303. The shutter device 302 controls a light irradiation period and a light blocking period with respect to the solid imaging device 303 according to control by the control circuit 304.

The solid imaging device 303 includes, for example, a package including the above-described solid imaging device 10. The solid imaging device 303 accumulates signal charges for a certain period according to light an image of which is formed on the light receiving surface via the optical system 301 and the shutter device 302. The signal charges accumulated in the solid imaging device 303 are transferred in accordance with a drive signal (timing signal) supplied from the control circuit 304.

The control circuit 304 outputs a drive signal that controls transfer operation of the solid imaging device 303 and shutter operation of the shutter device 302 and drives the solid imaging device 303 and the shutter device 302.

The signal processing circuit 305 performs various kinds of signal processing on the signal charges output from the solid imaging device 303. An image (image data) acquired by performance of the signal processing by the signal processing circuit 305 is supplied to and displayed on the monitor 306, or supplied to and stored (recorded) in the memory 307.

Also in the imaging device 300 configured in such a manner, by applying the above-described solid imaging device 10 as the solid imaging device 303, it is possible to realize imaging with low noise in all pixels along with an improvement in characteristics of the SPAD pixels 20, 20A, and 20a to 20h.

### <11-2. Ranging Device>

Next, a ranging device 400 will be described with reference to FIG. 20. FIG. 20 is a diagram depicting a schematic configuration example of the ranging device 400 as an electronic device to which the present technology is applied.

As depicted in FIG. 15, the ranging device (distance image sensor) 400 includes an optical system 401, a sensor chip 402, an image processing circuit 403, a monitor 404, and a memory 405. The ranging device 400 can acquire a distance image corresponding to a distance to a subject by receiving light projected from a light source device 410 toward the subject and reflected on a surface of the subject (modulated light or pulsed light).

The optical system 401 includes one or a plurality of lenses. The optical system 401 guides image light (incident light) from the subject to the sensor chip 402 and forms an image on a light receiving surface (sensor section) of the sensor chip 402.

The sensor chip 402 includes, for example, a package including the above-described solid imaging device 10. A distance signal indicating a distance acquired from a light reception signal (APD OUT) output from the sensor chip 402 is supplied to the image processing circuit 403.

The image processing circuit 403 performs image processing of constructing a distance image on the basis of the distance signal supplied from the sensor chip 402. The distance image (image data) acquired by the image processing is supplied to and displayed on the monitor 404, or supplied to and stored (recorded) in the memory 405.

In the ranging device 400 configured in such a manner, by applying the above-described solid imaging device 10 as the sensor chip 402, for example, it is possible to acquire a more accurate distance image along with an improvement in characteristics of the SPAD pixels 20, 20A, and 20a to 20h.

The above-described ranging device 400 can be used, for example, in various cases of sensing light such as visible light, infrared light, ultraviolet light, and X-rays as described below. For example, the ranging device 400 is used for a “device that photographs an image to be used for viewing, such as a digital camera or portable device with a camera function”, a “device used for traffic, such as an in-vehicle sensor that photographs the front, rear, surroundings, inside, and the like of an automobile for safe driving such as automatic stop, recognition of a condition of a driver, and the like, a monitoring camera that monitors a traveling vehicle and road, and a ranging sensor that measures a distance between vehicles and the like”, a “device used for home electric appliances such as a TV, a refrigerator, and an air conditioner in order to photograph a gesture of a user and perform device operation corresponding to the gesture”, a “device used for medical care or health care, such as an endoscope or a device that performs angiography by receiving infrared light”, a “device used for security, such as a monitoring camera for crime prevention or a camera for person authentication”, a “device used for beauty care, such as a skin measuring instrument that photographs skin or a microscope that photographs a scalp”, a “device used for sports, such as an action camera or a wearable camera for sports or the like”, a “device used for agriculture, such as a camera for monitoring conditions of a field and crop”, and the like. Note that the imaging device 300 can be similarly used in various cases.

### 12. APPLICATION EXAMPLE

Furthermore, a technology according to the present disclosure can be applied to various products. For example, the technology according to the present disclosure may be realized as a device such as an electronic device mounted on any type of mobile bodies such as an automobile, an electric vehicle, a hybrid electric vehicle, a motorcycle, a bicycle, a personal mobility, an airplane, a drone, a ship, a robot, a construction machine, and an agricultural machine (tractor). Furthermore, for example, the technology according to the present disclosure may be applied to an endoscopic surgical system, a microscopic surgical system, or the like.

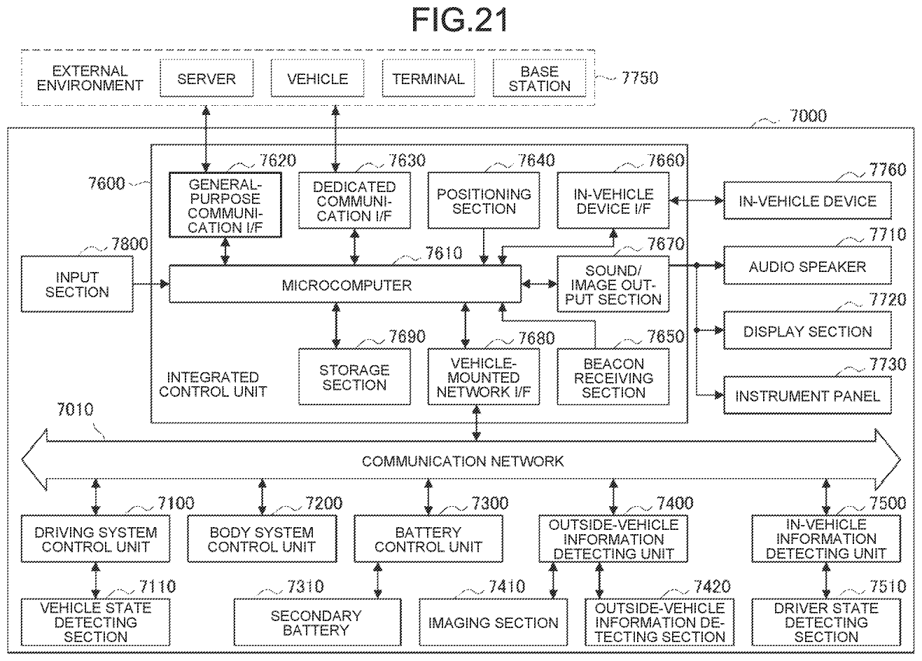

FIG. 21 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 21, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 21 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

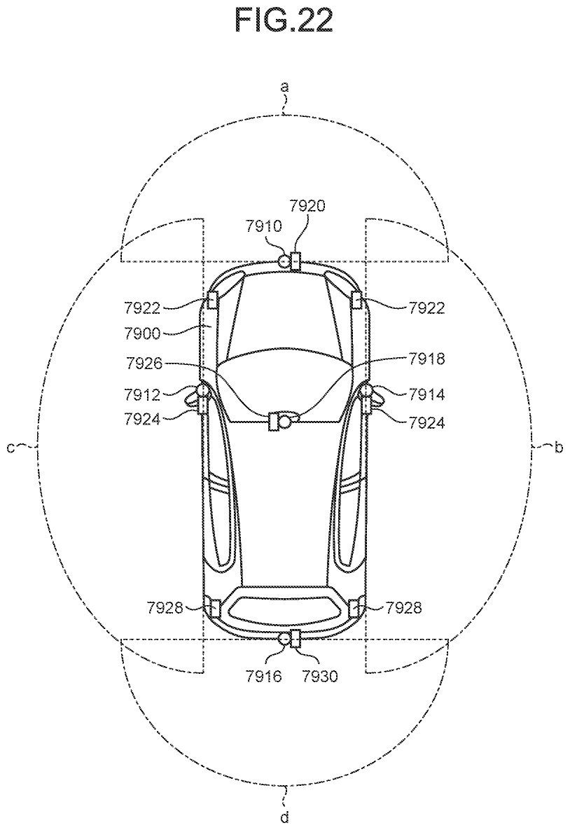

FIG. 22 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 21, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 21, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 21 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

Note that a computer program for realizing each function of the electronic device 1 according to the present embodiment described with reference to FIG. 1 can be mounted on any control unit or the like. Furthermore, it is also possible to provide a computer-readable recording medium that stores such a computer program. The recording medium is, for example, a magnetic disk, an optical disk, a magneto-optical disk, a flash memory, or the like. Furthermore, the computer program described above may be distributed via, for example, a network without utilization of the recording medium.

In the vehicle control system 7000 described above, the electronic device 1 according to the present embodiment described with reference to FIG. 1 can be applied to the integrated control unit 7600 of the application example depicted in FIG. 21. For example, the storage section 40 and the processor 50 of the electronic device 1 correspond to the microcomputer 7610, the storage section 7690, and the vehicle-mounted network I/F 7680 of the integrated control unit 7600. However, this is not a limitation, and the vehicle control system 7000 may correspond to a host.

In addition, at least some components of the electronic device 1 according to the present embodiment described with reference to FIG. 1 may be realized in a module for the integrated control unit 7600 depicted in FIG. 21 (such as an integrated circuit module including one die). Alternatively, the electronic device 1 according to the present embodiment described with reference to FIG. 1 may be realized by a plurality of control units of the vehicle control system 7000 depicted in FIG. 21.

Although embodiments of the present disclosure have been described above, the technical scope of the present disclosure is not limited to the above-described embodiments as they are, and various modifications can be made within the spirit and scope of the present disclosure. In addition, components of different embodiments and modification examples may be arbitrarily combined.

Also, an effect in each of the embodiments described in the present description is merely an example and is not a limitation, and there may be a different effect.

### 13. APPENDIX

Note that the present technology can also have the following configurations.

(1)

A solid imaging device comprising:
a semiconductor substrate including a plurality of photoelectric conversion elements that photoelectrically converts light incident from a light incident surface; and
an element isolation section that is provided in a lattice shape on the semiconductor substrate and partitions the plurality of photoelectric conversion elements, wherein
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact, and
one end of the first electrode which end is on the opposite side of the side of the light incident surface is placed on the side of the light incident surface compared to a contact surface between the second semiconductor region and the third semiconductor region in a height direction.

(2)

The solid imaging device according to (1), wherein
the photoelectric conversion element further includes
a metal section that is provided in the element isolation section, extends from the opposite side of the side of the light incident surface toward the first electrode, and is not in contact with the first electrode.

(3)

The solid imaging device according to (2), wherein
one end of the metal section which end is on the side of the light incident surface is placed on the side of the light incident surface compared to the contact surface between the second semiconductor region and the third semiconductor region in the height direction.

(4)

The solid imaging device according to (2) or (3), wherein
a predetermined voltage is applied to the metal section.

(5)

The solid imaging device according to (4), wherein
the predetermined voltage is higher than a voltage applied to the first electrode and lower than a voltage applied to the second electrode.

(6)

The solid imaging device according to (4), wherein
the predetermined voltage is lower than a voltage applied to the first electrode.

(7)

The solid imaging device according to any one of (2) to (6), wherein
the photoelectric conversion element further includes
an insulating layer that has a light blocking property and is provided between the first electrode and the metal section.

(8)

The solid imaging device according to (7), wherein
the insulating layer is a gas layer having the light blocking property and an insulating property.

(9)

The solid imaging device according to any one of (2) to (8), wherein
the first contact is provided on the side of the light incident surface.

(10)

A solid imaging device comprising:
a semiconductor substrate including a plurality of photoelectric conversion elements that photoelectrically converts light incident from a light incident surface; and
an element isolation section that is provided in a lattice shape on the semiconductor substrate and partitions the plurality of photoelectric conversion elements, wherein
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact,
one end of the first electrode which end is on the opposite side of the side of the light incident surface is placed on the opposite side of the side of the light incident surface compared to a contact surface between the second semiconductor region and the third semiconductor region in a height direction, and
the photoelectric conversion element further includes
a metal section that is provided between the third semiconductor region and the first electrode in the element isolation section and that is not in contact with the first electrode.

(11)

The solid imaging device according to (10), wherein
the metal section is formed in a shape of sandwiching the first electrode in a manner of covering the one end of the first electrode which end is on the opposite side of the side of the light incident surface and in a manner of not being in contact with the first electrode.

(12)

The solid imaging device according to (10) or (11), wherein
a predetermined voltage is applied to the metal section.

(13)

The solid imaging device according to (12), wherein
the predetermined voltage is higher than a voltage applied to the first electrode and lower than a voltage applied to the second electrode.

(14)

The solid imaging device according to (12), wherein
the predetermined voltage is lower than a voltage applied to the first electrode.

(15)

An electronic device comprising:
a solid imaging device; and
an optical system that forms an image of light on a light receiving surface of the solid imaging device, wherein
the solid imaging device includes
a semiconductor substrate including a plurality of photoelectric conversion elements that photoelectrically converts light incident from a light incident surface, and
an element isolation section that is provided in a lattice shape on the semiconductor substrate and partitions the plurality of photoelectric conversion elements,
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact, and
one end of the first electrode which end is on the opposite side of the side of the light incident surface is placed on the side of the light incident surface compared to a contact surface between the second semiconductor region and the third semiconductor region in a height direction.

(16)

An electronic device comprising:
a solid imaging device; and
an optical system that forms an image of light on a light receiving surface of the solid imaging device, wherein
the solid imaging device includes
a semiconductor substrate including a plurality of photoelectric conversion elements that photoelectrically converts light incident from a light incident surface, and
an element isolation section that is provided in a lattice shape on the semiconductor substrate and partitions the plurality of photoelectric conversion elements,
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact,
one end of the first electrode which end is on the opposite side of the side of the light incident surface is placed on the opposite side of the side of the light incident surface compared to a contact surface between the second semiconductor region and the third semiconductor region in a height direction, and
the photoelectric conversion element further includes
a metal section that is provided between the third semiconductor region and the first electrode in the element isolation section, and that is not in contact with the first electrode.

(17)

An electronic device including:
the solid imaging device according to any one of (1) to (14); and
an optical system that forms a light image on a light receiving surface of the solid imaging device.

### REFERENCE SIGNS LIST

1 ELECTRONIC DEVICE
10 SOLID IMAGING DEVICE
11 SPAD ARRAY SECTION
12 DRIVE CIRCUIT
13 OUTPUT CIRCUIT
15 TIMING CONTROL CIRCUIT
20 SPAD PIXEL
20A SPAD PIXEL
20a to 20h SPAD PIXEL
21 PHOTODIODE
22 READOUT CIRCUIT
23 QUENCH RESISTOR
24 SELECTION TRANSISTOR
25 DIGITAL CONVERTER
26 INVERTER
27 BUFFER
30 IMAGING LENS
40 STORAGE SECTION
50 PROCESSOR
60 COLOR FILTER ARRAY
61 UNIT PATTERN
71 LIGHT RECEIVING CHIP
72 CIRCUIT CHIP
101 SEMICONDUCTOR SUBSTRATE
102 PHOTOELECTRIC CONVERSION REGION
103N− TYPE SEMICONDUCTOR REGION
104 P TYPE SEMICONDUCTOR REGION
105 P+ TYPE SEMICONDUCTOR REGION
106 N+ TYPE SEMICONDUCTOR REGION
107 CATHODE CONTACT
108 ANODE CONTACT
108A ANODE CONTACT
109 INSULATING FILM
110 ELEMENT ISOLATION SECTION
111 ANODE ELECTRODE
112 INSULATING FILM
113 PINNING LAYER
114 FLATTENING FILM
115 COLOR FILTER
116 ON-CHIP LENS
120 WIRING LAYER
121 CATHODE ELECTRODE
122 METAL SECTION
122a METAL SECTION
123 INTERLAYER INSULATING FILM
124 WIRING LINE
125 CONNECTION PAD
131 INTERLAYER INSULATING FILM
132 WIRING LINE
135 CONNECTION PAD
141 SEMICONDUCTOR SUBSTRATE
142 CIRCUIT ELEMENT
250 INSULATING FILM
300 IMAGING DEVICE
301 OPTICAL SYSTEM
400 RANGING DEVICE
401 OPTICAL SYSTEM
T1 FIRST TRENCH
T2 SECOND TRENCH

1. A solid imaging device comprising:
a semiconductor substrate including a plurality of photoelectric conversion elements that photoelectrically converts light incident from a light incident surface; and
an element isolation section that is provided in a lattice shape on the semiconductor substrate and partitions the plurality of photoelectric conversion elements, wherein
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact, and
one end of the first electrode which end is on the opposite side of the side of the light incident surface is placed on the side of the light incident surface compared to a contact surface between the second semiconductor region and the third semiconductor region in a height direction.

2. The solid imaging device according to claim 1, wherein
the photoelectric conversion element further includes
a metal section that is provided in the element isolation section, extends from the opposite side of the side of the light incident surface toward the first electrode, and is not in contact with the first electrode.

3. The solid imaging device according to claim 2, wherein
one end of the metal section which end is on the side of the light incident surface is placed on the side of the light incident surface compared to the contact surface between the second semiconductor region and the third semiconductor region in the height direction.

4. The solid imaging device according to claim 2, wherein
a predetermined voltage is applied to the metal section.

5. The solid imaging device according to claim 4, wherein
the predetermined voltage is higher than a voltage applied to the first electrode and lower than a voltage applied to the second electrode.

6. The solid imaging device according to claim 4, wherein
the predetermined voltage is lower than a voltage applied to the first electrode.

7. The solid imaging device according to claim 2, wherein
the photoelectric conversion element further includes
an insulating layer that has a light blocking property and is provided between the first electrode and the metal section.

8. The solid imaging device according to claim 7, wherein
the insulating layer is a gas layer having the light blocking property and an insulating property.

9. The solid imaging device according to claim 2, wherein
the first contact is provided on the side of the light incident surface.

10. A solid imaging device comprising:
a semiconductor substrate including a plurality of photoelectric conversion elements that photoelectrically converts light incident from a light incident surface; and
an element isolation section that is provided in a lattice shape on the semiconductor substrate and partitions the plurality of photoelectric conversion elements, wherein
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact,
one end of the first electrode which end is on the opposite side of the side of the light incident surface is placed on the opposite side of the side of the light incident surface compared to a contact surface between the second semiconductor region and the third semiconductor region in a height direction, and
the photoelectric conversion element further includes
a metal section that is provided between the third semiconductor region and the first electrode in the element isolation section and that is not in contact with the first electrode.

11. The solid imaging device according to claim 10, wherein
the metal section is formed in a shape of sandwiching the first electrode in a manner of covering the one end of the first electrode which end is on the opposite side of the side of the light incident surface and in a manner of not being in contact with the first electrode.

12. The solid imaging device according to claim 10, wherein
a predetermined voltage is applied to the metal section.

13. The solid imaging device according to claim 12, wherein
the predetermined voltage is higher than a voltage applied to the first electrode and lower than a voltage applied to the second electrode.

14. The solid imaging device according to claim 12, wherein
the predetermined voltage is lower than a voltage applied to the first electrode.

15. An electronic device comprising:
a solid imaging device; and
an optical system that forms an image of light on a light receiving surface of the solid imaging device, wherein
the solid imaging device includes
a semiconductor substrate including a plurality of photoelectric conversion elements that photoelectrically converts light incident from a light incident surface, and
an element isolation section that is provided in a lattice shape on the semiconductor substrate and partitions the plurality of photoelectric conversion elements,
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact, and
one end of the first electrode which end is on the opposite side of the side of the light incident surface is placed on the side of the light incident surface compared to a contact surface between the second semiconductor region and the third semiconductor region in a height direction.

16. An electronic device comprising:
a solid imaging device; and
an optical system that forms an image of light on a light receiving surface of the solid imaging device, wherein
the solid imaging device includes
a semiconductor substrate including a plurality of photoelectric conversion elements that photoelectrically converts light incident from a light incident surface, and
an element isolation section that is provided in a lattice shape on the semiconductor substrate and partitions the plurality of photoelectric conversion elements,
the photoelectric conversion element includes
a photoelectric conversion region that is provided in an element region partitioned by the element isolation section and that photoelectrically converts the light incident from the light incident surface and generates a charge,
a first semiconductor region that is provided in the element region and that surrounds the photoelectric conversion region,
a first contact that is provided in the element region and that is in contact with the first semiconductor region,
a first electrode that is provided in the element isolation section, extends from a side of the light incident surface along the element isolation section, and is in contact with the first contact,
a second semiconductor region that is provided in the element region, is in contact with the first semiconductor region, and has a first conductivity type same as that of the first semiconductor region,
a third semiconductor region that is provided in the element region, is in contact with an opposite side of the side of the light incident surface in the second semiconductor region, and has a second conductivity type opposite to the first conductivity type,
a second contact that is provided in the element region and in contact with the third semiconductor region, and
a second electrode that is in contact with the second contact,
one end of the first electrode which end is on the opposite side of the side of the light incident surface is placed on the opposite side of the side of the light incident surface compared to a contact surface between the second semiconductor region and the third semiconductor region in a height direction, and
the photoelectric conversion element further includes
a metal section that is provided between the third semiconductor region and the first electrode in the element isolation section, and that is not in contact with the first electrode.
